(19) United States
(12) Patent Application Publication
(10) Pub. No.: US 2011/0315536 A1
(43) Pub. Date: Dec. 29, 2011

(54) TOUCH PANEL

(75) Inventors: Jeng-Maw Chiou, Hsinchu County (TW); Te-Hao Tsou, Hsinchu County (TW); Biing-Nan Lin, Hsinchu County (TW); Tzyy-Jang Tseng, Hsinchu County (TW)

(73) Assignee: UNIDISPLAY INC., Hsinchu County (TW)

(21) Appl. No.: 13/038,389

(22) Filed: Mar. 2, 2011

(30) Foreign Application Priority Data
Jun. 29, 2010 (TW) 99121232

(51) Int. Cl. H03K 17/975

(52) U.S. Cl. 200/600

(57) ABSTRACT

A touch panel including a substrate, a first patterned conductive layer, a second patterned conductive layer and a circuit board is provided. The substrate has a first surface, a second surface, a first bonding area and a second bonding area. The first patterned conductive layer disposed on the first surface includes first sensing series electrically insulated from each other. The second patterned conductive layer disposed on the second surface includes second sensing series electrically insulated from each other. The circuit board includes a rigid portion, a first flexible bonding portion and a second flexible bonding portion. The first flexible bonding portion and the second flexible bonding portion are electrically connected to the rigid portion. The first flexible bonding portion is electrically connected to the first sensing series in the first bonding area. The second flexible bonding portion is electrically connected to the second sensing series in the second bonding area.

### CROSS-REFERENCE TO RELATED APPLICATION

This application claims the priority benefit of Taiwan application serial no. 99121232, filed Jun. 29, 2010. The entirety of the above-mentioned patent application is hereby incorporated by reference herein and made a part of this specification.

### BACKGROUND

1. Field of the Invention

The invention relates to a touch panel. More particularly, the invention relates to a capacitive touch panel.

2. Description of Related Art

Touch panels are approximately grouped into resistive touch panels, capacitive touch panels, optical touch panels, acoustic wave touch panels and electromagnetic touch panels according to different sensing methods. Since the capacitive touch panel has advantages of fast response time, good reliability and high durability, etc., the capacitive touch panel has been widely applied in various electronic products.

Generally, the capacitive touch panel includes a substrate, a plurality of first sensing series extending along a first direction and a plurality of second sensing series extending along a second direction, wherein the first sensing series and the second sensing series are all located on a surface of the substrate, and each of the first sensing series is formed by a plurality of first sensing pads and first bridge portions connected in series is formed by a plurality of first sensing pads and first bridge portions connected in series, and each of the second sensing series is formed by a plurality of second sensing pads and second bridge portions connected in series. The first sensing pads and the second sensing pads may form a sensing array, so as to achieve touch-sensing effect.

Therefore, when a user touches the touch panel by a finger, the first sensing series and the second sensing series of the touch panel may have a capacitance variation at a touch position touch by the finger. Since the touch panel is electrically connected to a printed circuit board through a flexible printed circuit (FPC), when the capacitance variation is converted into a control signal, the control signal is transmitted to an external circuit (for example, a control circuit board) through the flexible printed circuit (FPC) and the printed circuit board, and then the control signal is processed to output a suitable command for controlling an electronic device.

### SUMMARY

The invention is directed to a touch panel, which has advantages of low production cost and high throughput and yield rate.

The invention provides a touch panel including a substrate, a first patterned conductive layer, a second patterned conductive layer and a circuit board. The substrate has a first surface, a second surface, a first bonding area located at an edge of the first surface and a second bonding area located at an edge of the second surface. The first patterned conductive layer is disposed on the first surface and includes a plurality of first sensing series electrically insulated from each other. An end of each first sensing series extends to the first bonding area. The second patterned conductive layer is disposed on the second surface and includes a plurality of second sensing series electrically insulated from each other. An end of each second sensing series extends to the second bonding area. The circuit board includes a rigid portion, a first flexible bonding portion and a second flexible bonding portion. The first flexible bonding portion and the second flexible bonding portion are electrically connected to the rigid portion. The first flexible bonding portion is electrically connected to the first sensing series in the first bonding area. The second flexible bonding portion is electrically connected to the second sensing series in the second bonding area.

The invention provides a touch panel including a substrate, a first patterned conductive layer, a second patterned conductive layer, a first circuit board, a second circuit board and a connection circuit. The substrate has a first surface, a second surface, a first bonding area located at an edge of the first surface and a second bonding area located at an edge of the second surface. The first patterned conductive layer is disposed on the first surface and includes a plurality of first sensing series electrically insulated from each other. An end of each first sensing series extends to the first bonding area. The second patterned conductive layer is disposed on the second surface and includes a plurality of second sensing series electrically insulated from each other. An end of each second sensing series extends to the second bonding area. The first circuit board includes a first rigid portion and a first flexible bonding portion electrically connected to the first rigid portion. The first flexible bonding portion is electrically connected to the first sensing series in the first bonding area. The second circuit board includes a second rigid portion and a second flexible bonding portion electrically connected to the second rigid portion. The second flexible bonding portion is electrically connected to the second sensing series in the second bonding area. The connection circuit is electrically connected to the first rigid portion and the second rigid portion.

According to the above descriptions, since the touch panel of the invention applies the circuit board having both of the rigid portion and the flexible bonding portions, the first patterned conductive layer and the second patterned conductive layer on the substrate can be directly connected to the flexible bonding portions, and a chip or a control circuit can be directly connected to the circuit board. In this way, a production cost of the touch panel is reduced, and throughput and yield rate thereof are increased.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a top view of a touch panel according to an embodiment of the invention.

FIG. 1B is a bottom view of a touch panel of FIG. 1A.

FIG. 1C is a cross-sectional view of a touch panel of FIG. 1A along an I-I line.

FIG. 1D is a cross-sectional view of a touch panel of FIG. 1A along an II-II line.

FIG. 2A is a top view of a touch panel according to another embodiment of the invention.

FIG. 2B is a bottom view of a touch panel of FIG. 2A.

FIG. 3A is a top view of a touch panel according to still another embodiment of the invention.

FIG. 3B is a cross-sectional view of a touch panel of FIG. 3A along an line.

FIG. 3C is a cross-sectional view of a touch panel of FIG. 3A along an IV-IV line.

FIG. 4 is a top view of a touch panel according to yet another embodiment of the invention.

FIG. 5A is a top view of a touch panel according to still another embodiment of the invention.

FIG. 5B is a cross-sectional view of a touch panel of FIG. 5A along a V-V line.

FIG. 5C is a cross-sectional view of a touch panel of FIG. 5A along a VI-VI line.

FIG. 6 is a cross-sectional view of a touch panel according to still another embodiment of the invention.

FIG. 7A is a top view of a touch panel according to still another embodiment of the invention.

FIG. 7B is a bottom view of a touch panel of FIG. 7A.

FIG. 7C is a cross-sectional view of a touch panel of FIG. 7A along a VII-VII line.

FIG. 7D is a cross-sectional view of a touch panel of FIG. 7A along a VIII-VIII line.

FIG. 8A is a top view of a touch panel according to still another embodiment of the invention.

FIG. 8B is a top view of a touch panel according to still another embodiment of the invention.

### DETAILED DESCRIPTION OF DISCLOSED EMBODIMENTS

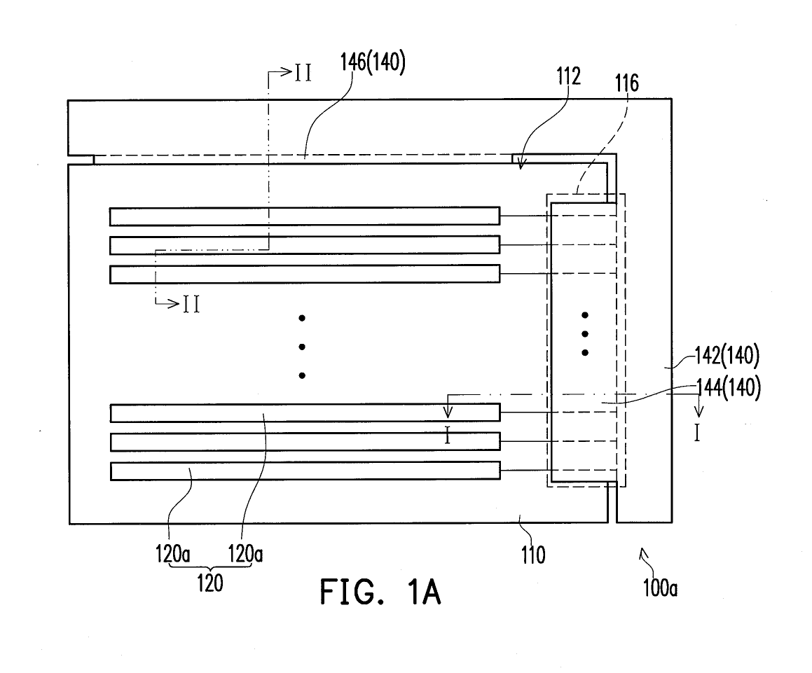

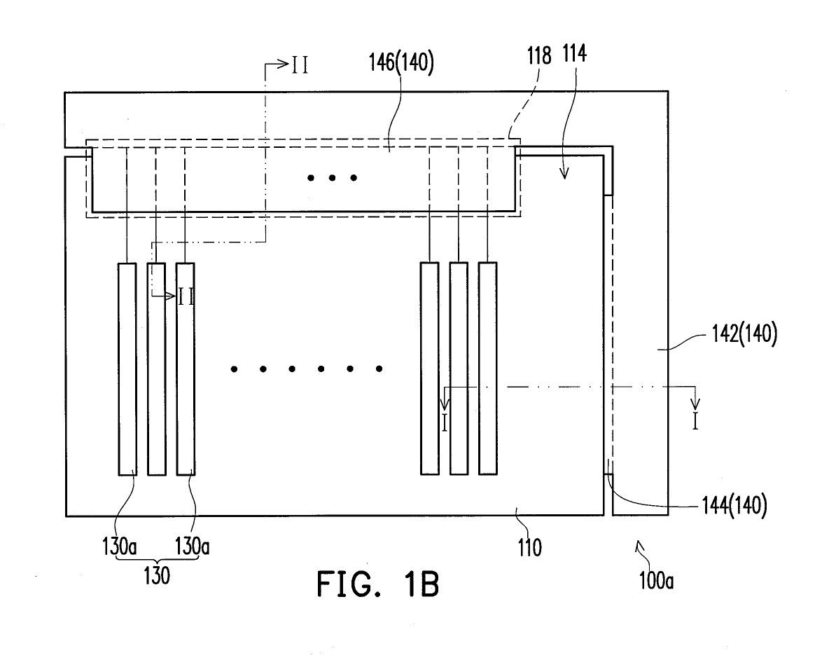

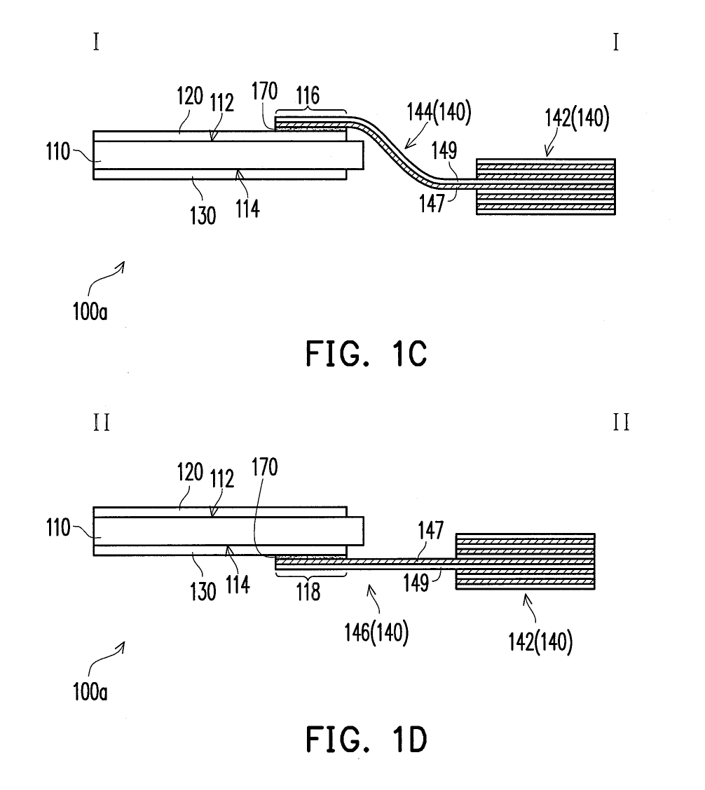

FIG. 1A is a top view of a touch panel according to an embodiment of the invention. FIG. 1B is a bottom view of the touch panel of FIG. 1A. Referring to FIG. 1A and FIG. 1B, in the present embodiment, the touch panel 100a includes a substrate 110, a first patterned conductive layer 120, a second patterned conductive layer 130 and a circuit board 140.

In detail, the substrate 110 has a first surface 112, a second surface 114, a first bonding area 116 located at an edge of the first surface 112 and a second bonding area 118 located at an edge of the second surface 114. The first patterned conductive layer 120 is disposed on the first surface 112. The first patterned conductive layer 120 includes a plurality of first sensing series 120a electrically insulated from each other, and an end of each first sensing series 120a extends to the first bonding area 116. The second patterned conductive layer 130 is disposed on the second surface 114. The second patterned conductive layer 130 includes a plurality of second sensing series 130a electrically insulated from each other, and an end of each second sensing series 130a extends to the second bonding area 118. Namely, the first patterned conductive layer 120 and the second patterned conductive layer 130 all have a design of unilateral output. Moreover, in the present embodiment, shapes of the first sensing series 120a and the second sensing series 130a are strips.

In the present embodiment, the substrate 110 is, for example, a transparent substrate, an opaque substrate, or a translucent substrate, wherein a material of the substrate 110 is preferably glass, polycarbonate (PC), polymethyl methacrylate (PMMA) or polyethylene terephthalate (PET), and a thickness of the substrate 110 is preferably between about 0.1 mm and about 2 mm. Moreover, the first patterned conductive layer 120 and the second patterned conductive layer 130 are, for example, respectively a transparent patterned conductive layer, an opaque patterned conductive layer or a translucent patterned conductive layer, wherein a material of the first patterned conductive layer 120 and the second patterned conductive layer 130 is preferably indium tin oxide, transparent conducting oxide (TCO) or a transparent conductive material containing nano-materials. If the first patterned conductive layer 120 and the second patterned conductive layer 130 are all fabricated by the transparent conductive material, the touch panel 100a of the present embodiment may provide a good light penetrability.

FIG. 1C is a cross-sectional view of the touch panel of FIG. 1A along an I-1 line. FIG. 1D is a cross-sectional view of the touch panel of FIG. 1A along an II-II line. Referring to FIG. 1A, FIG. 1B, FIG. 1C and FIG. 1D, particularly, the circuit board 140 of the touch panel 100a of the present embodiment includes a rigid portion 142, a first flexible bonding portion 144 and a second flexible bonding portion 146. The first flexible bonding portion 144 and the second flexible bonding portion 146 are electrically connected to the rigid portion 142. The first flexible bonding portion 144 is electrically connected to the first sensing series 120a in the first bonding area 116. The second flexible bonding portion 146 is electrically connected to the second sensing series 130a in the second bonding area 118.

It should be noticed that in the present embodiment, the rigid portion 142 of the circuit board 140 includes a plurality of conductive layers 147 and dielectric layers 149 stacked alternately, wherein a part of the conductive layers 147 and the dielectric layers 149 in the rigid portion 142 extends outward to form the first flexible bonding portion 144 and the second flexible bonding portion 146. Namely, the structure of the circuit board 140 can be regarded as a flexible-hard board structure. Moreover, a shape of the rigid portion 142 of the circuit board 140 is, for example, an L-shape.

In addition, the touch panel 100a of the present embodiment further includes two anisotropic conductive films 170, wherein the anisotropic conductive films 170 are respectively disposed between the end of the first sensing series 120a and the first flexible bonding portion 144 of the circuit board 140, and between the end of the second sensing series 130a and the second flexible bonding portion 146 of the circuit board 140. Namely, the anisotropic conductive films 170 directly contact to the first patterned conductive layer 120 and the second patterned conductive layer 130. Since the anisotropic conductive films 170 directly contact to the first patterned conductive layer 120 and the second patterned conductive layer 130, adhesions respectively between the first flexible bonding portion 144 and the substrate 110, and the second flexible bonding portion 146 and the substrate 110 are increased, and generation of contact impedance is reduced.

Since the first patterned conductive layer 120 and the second patterned conductive layer 130 are respectively disposed on the first surface 112 and the second surface 114 of the substrate 110, the touch panel 100a of the present embodiment can be regarded as a double-sided touch panel. Moreover, since the first patterned conductive layer 120 and the second patterned conductive layer 130 all applies the design of unilateral output, when the circuit board 140 is assembled to the substrate 110 for electrically connecting the first sensing series 120a and the second sensing series 130a, an assembling difficulty thereof is reduced, and an assembling rate and an yield rate thereof are increased.

Moreover, since the circuit board 140 of the present embodiment simultaneously have the rigid portion 142 and the flexible bonding portions (i.e. the first flexible bonding portion 144 and the second flexible bonding portion 146), and the flexible bonding portions are formed by extending out a part of the conductive layers 147 and the dielectric layers 149 in the rigid portion 142, the first patterned conductive layer 120 and the second patterned conductive layer 130 on the substrate 110 can be directly connected to the first flexible bonding portion 144 and the second flexible bonding portion 146, respectively, and the rigid portion 142 of the circuit board 140 can be further electrically connected to an external circuit (not shown), so that a touch position can be obtained through computation processing. In this way, a production cost of the touch panel 100a of the present embodiment can be effectively reduced, and assembling steps thereof can be simplified, so as to increase a throughput and operation convenience thereof.

In addition, a design of the touch panel 100a is not limited by the invention. A plurality of embodiments is provided below to introduce designs of following touch panels 100b-100f. It should be noticed that the same reference numbers in the aforementioned embodiment are used to represent the same or like parts, and the same technical descriptions are omitted.

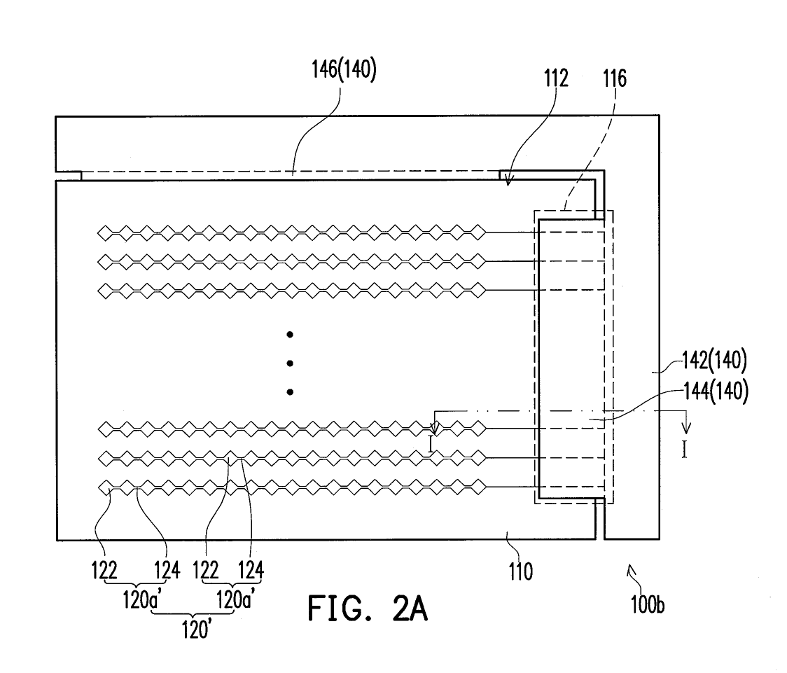

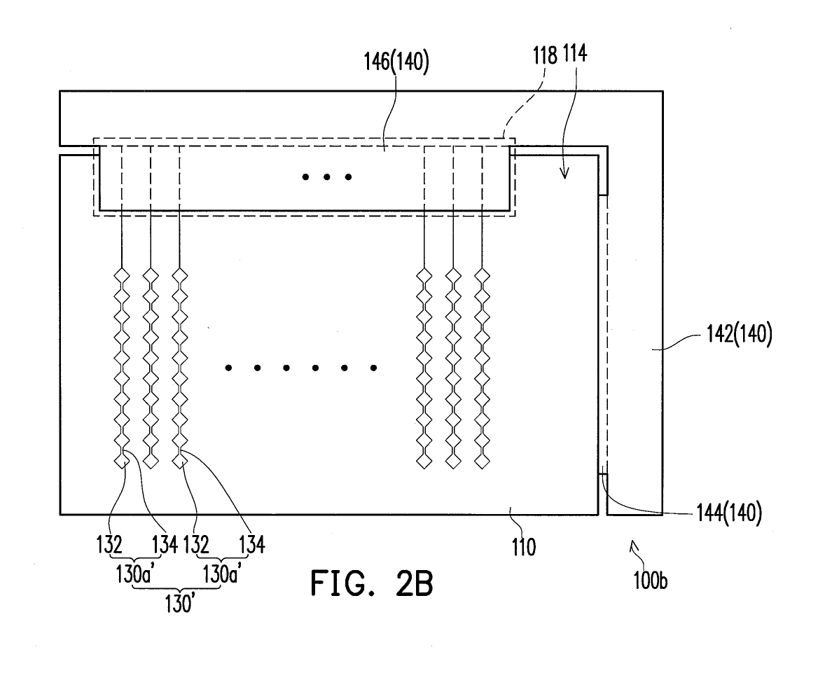

FIG. 2A is a top view of a touch panel according to another embodiment of the invention. FIG. 2B is a bottom view of the touch panel of FIG. 2A. Referring to FIG. 1A, FIG. 1B, FIG. 2A and FIG. 2B, in the present embodiment, the touch panel 100b of FIG. 2A and FIG. 2B is similar to the touch panel 100a of FIG. 1A and FIG. 1B, and a difference there between lies in designs of the first patterned conductive layer 120′ and the second patterned conductive layer 130′ of the touch panel 100b in FIG. 2A and FIG. 2B.

In detail, each of the first sensing series 120a′ of the present embodiment includes a plurality of first sensing pads 122 and a plurality of first bridge portions 124, wherein each of the first bridge portions 124 is electrically connected between two neighboring first sensing pads 122. Each of the second sensing series 130a′ includes a plurality of second sensing pads 132 and a plurality of second bridge portions 134, wherein each of the second bridge portions 134 is electrically connected between two neighboring second sensing pads 132. In brief, the touch panel 100b of the present embodiment is, for example, a projected capacitive touch panel.

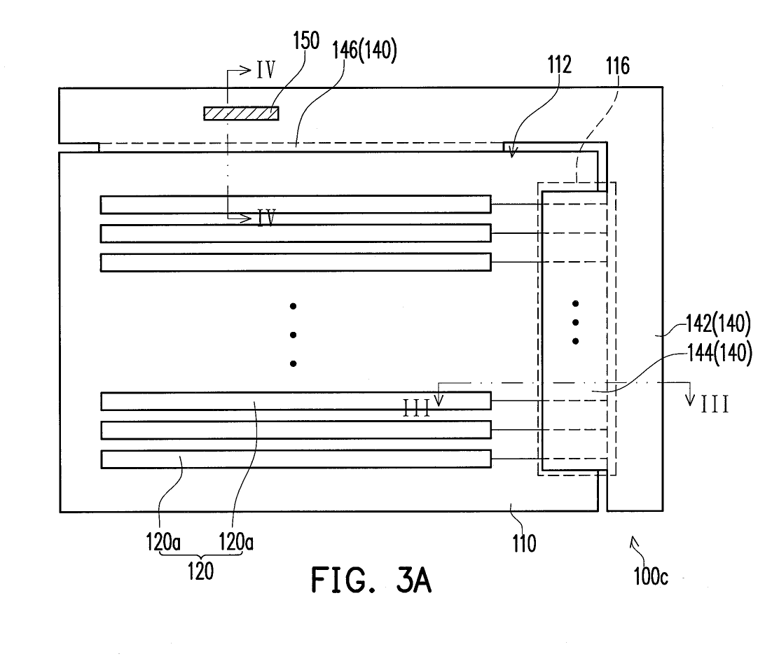

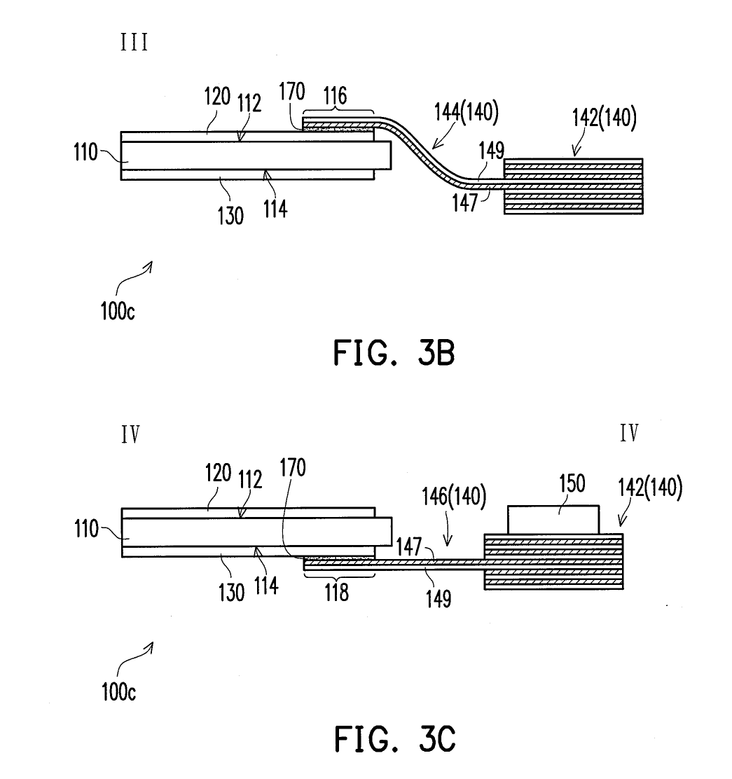

FIG. 3A is a top view of a touch panel according to still another embodiment of the invention. FIG. 3B is a cross-sectional view of the touch panel of FIG. 3A along an line. FIG. 3C is a cross-sectional view of the touch panel of FIG. 3A along an IV-IV line. Referring to FIG. 1A, FIG. 1C, FIG. 1D, FIG. 3A, FIG. 3B and FIG. 3C, in the present embodiment, the touch panel 100c of FIG. 3A, FIG. 3B and FIG. 3C is similar to the touch panel 100a of FIG. 1A, FIG. 1C and FIG. 1D, and a difference there between is that the touch panel 100c of FIG. 3A, FIG. 3B and FIG. 3C further includes at least one chip 150. The chip 150 is disposed on the rigid portion 142 of the circuit board 140, and is electrically connected to the circuit board 140. Since the first patterned conductive layer 120 and the second patterned conductive layer 130 can transmit signals to the chip 150 through the circuit board 140, coordinates of a touch point (not shown) can be calculated.

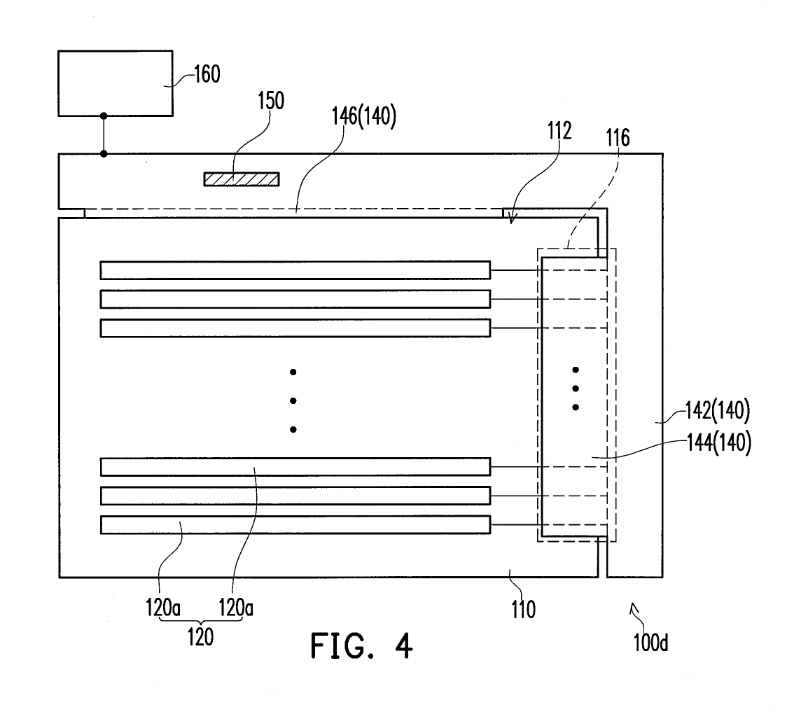

FIG. 4 is a top view of a touch panel according to yet another embodiment of the invention. Referring to FIG. 3A and FIG. 4, in the present embodiment, the touch panel 100d of FIG. 4 is similar to the touch panel 100c of FIG. 3A, and a difference there between is that the touch panel 100d of FIG. 4 further includes a control circuit 160. The control circuit 160 is electrically connected to the circuit board 140, wherein the first patterned conductive layer 120 and the second patterned conductive layer 130 (referring to FIG. 3B) are electrically connected to the control circuit 160 through the circuit board 140.

It should be noticed that positions and a number of the chips 150 are not limited by the invention, although the chip 150 of the present embodiment is disposed on the rigid portion 142 of the circuit board 140, and the number of the chip 150 is one, in other embodiments that are not illustrated, the number of the chips 150 can be increased according to a utilization requirement (i.e. the number of the chips 150 is two or more than two), and the chip 150 can also be disposed on the control circuit 160 and electrically connected to the control circuit 160. Certainly, the chip 150 can also be electrically connected to other external circuits (not shown), which is still considered to be a technical proposal of the invention without departing from the spirit and scope of the present invention.

Moreover, in the present embodiment, a main function of the control circuit 160 is, for example, data transmission or data processing. For example, the data transmission function of the control circuit 160 can be implemented by the circuit board 140, and the data processing function of the control circuit 160 can be implemented by the chip 150. Certainly, in other embodiments, preliminary data processing can also be implemented by the circuit board 140. The above implementations are only examples, and the invention is not limited thereto.

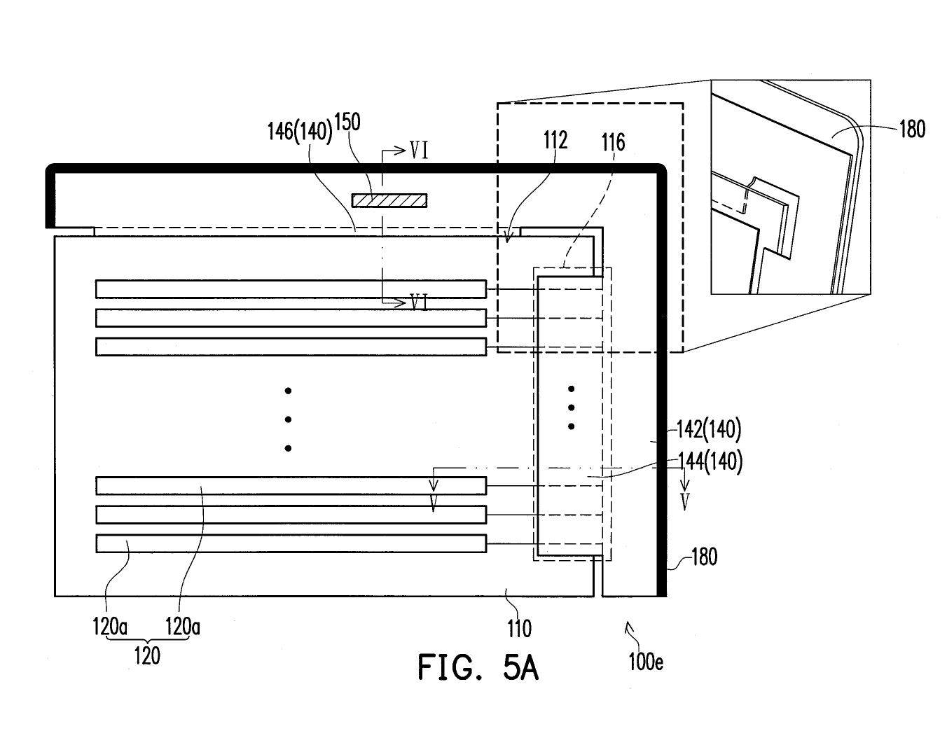

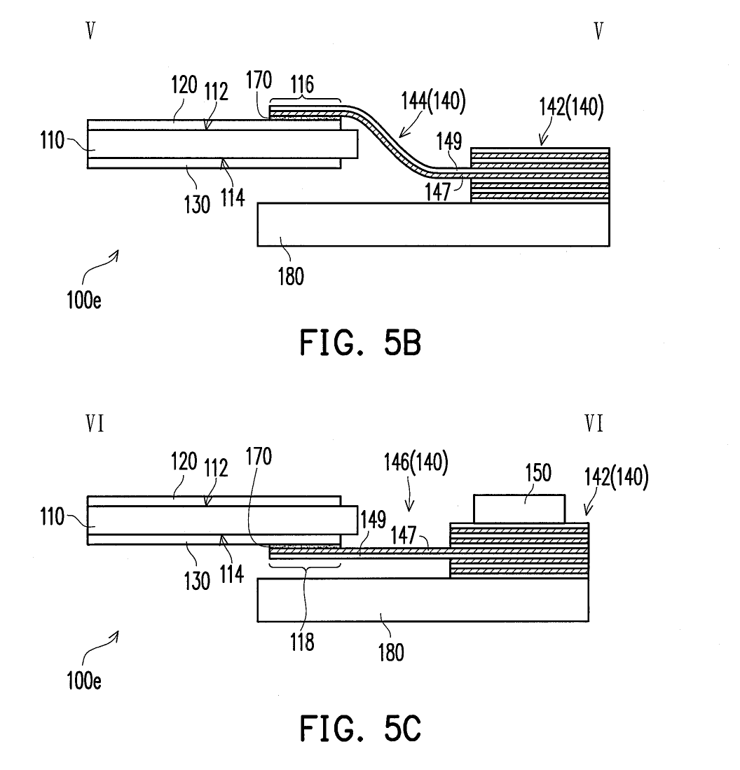

FIG. 5A is a top view of a touch panel according to still another embodiment of the invention. FIG. 5B is a cross-sectional view of the touch panel of FIG. 5A along a V-V line. FIG. 5C is a cross-sectional view of the touch panel of FIG. 5A along a VI-VI line. Referring to FIG. 3B, FIG. 3C, FIG. 5A, FIG. 5B and FIG. 5C, in the present embodiment, the touch panel 100e of FIG. 5A, FIG. 5B and FIG. 5C is similar to the touch panel 100c of FIG. 3B and FIG. 3C, and a difference there between is that the touch panel 100e of FIG. 5A, FIG. 5B and FIG. 5C further includes a support board 180, wherein the circuit board 140 is disposed on the support board 180, and the support board 180 surrounds the substrate 110. In the present embodiment, a shape of the support board 180 is, for example, an L-shape.

It should be noticed that to strengthen a structure strength of the display panel 100e, in other embodiments that are not illustrated, the shape of the support board 180 can also be a [symbol] -shape, a □-shape or other suitable shapes. If the shape of the support board 180 is the [symbol] -shape, it means that one of the first patterned conductive layer 120 and the second patterned conductive layer 130 has a design of bilateral output. Namely, two ends of the first sensing series 120a or two ends of the second sensing series 130a (referring to FIG. 1B) respectively output signals from two sides of the substrate 110. If the shape of the support board 180 is the □-shape, it means that both the first patterned conductive layer 120 and the second patterned conductive layer 130 have the design of bilateral output. Namely, two ends of the first sensing series 120a and two ends of the second sensing series 130a (referring to FIG. 1B) respectively output signals from two sides of the substrate 110. In other words, implementation of the support board 180 in the touch panel 100e is diversified, and the structure design thereof in FIG. 5A, FIG. 5B and FIG. 5C is only used as an example for those skilled in the art, and is not used to limit the present invention.

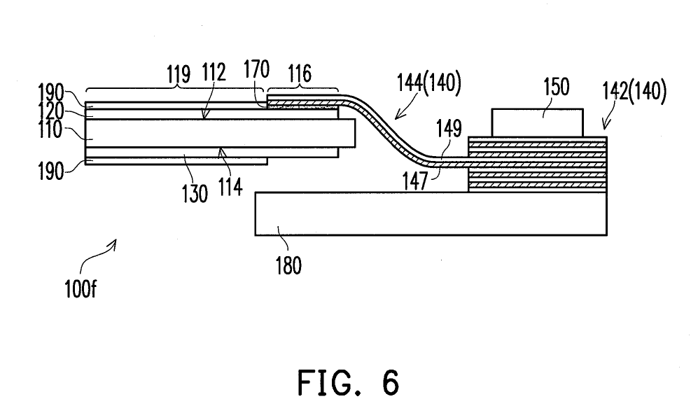

FIG. 6 is a cross-sectional view of a touch panel according to still another embodiment of the invention. Referring to FIG. 6 and FIG. 5B, in the present embodiment, the touch panel 100f of FIG. 6 is similar to the touch panel 100e of FIG. 5B, and a difference there between is that the touch panel 100f of FIG. 6 further includes at least a protection film 190 (two protection films are illustrated in FIG. 6), wherein the protection films 190 are respectively disposed on the first surface 112 and the second surface 114 of the substrate 110. In the present embodiment, the protection films 190 are mainly adhered to touch sensing areas (i.e. areas other than the first bonding area 116 and the second bonding area 118) of the substrate 110, and cover the first patterned conductive layer 120 and/or the second patterned conductive layer 130. For example, the protection films 190 are adhered to the touch sensing areas (i.e. the areas other than the first bonding area 116 and the second bonding area 118) of the substrate 110 through film adhesion, liquid type coating film or gas type coating film. Moreover, the protection film 190 is, for example, an anti-reflection film, an anti-glare film, an anti-grease film, a circuit visibility reduction film or other functional films, which is used for protecting the first patterned conductive layer 120 and the second patterned conductive layer 130.

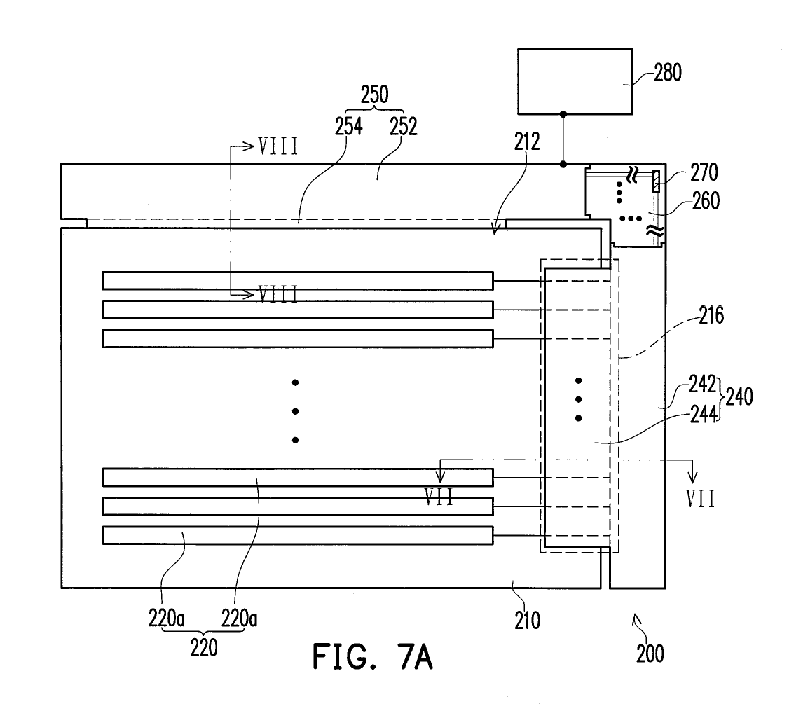

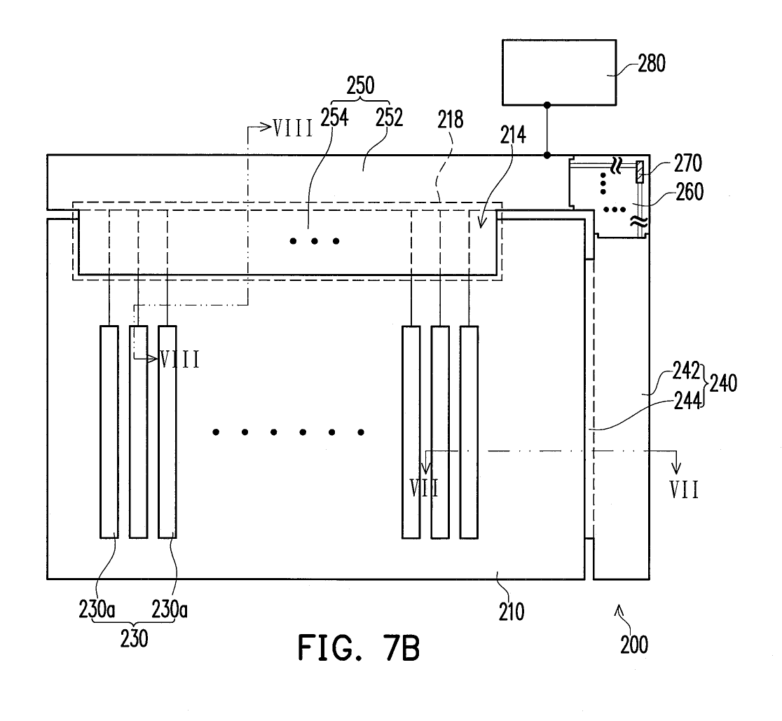

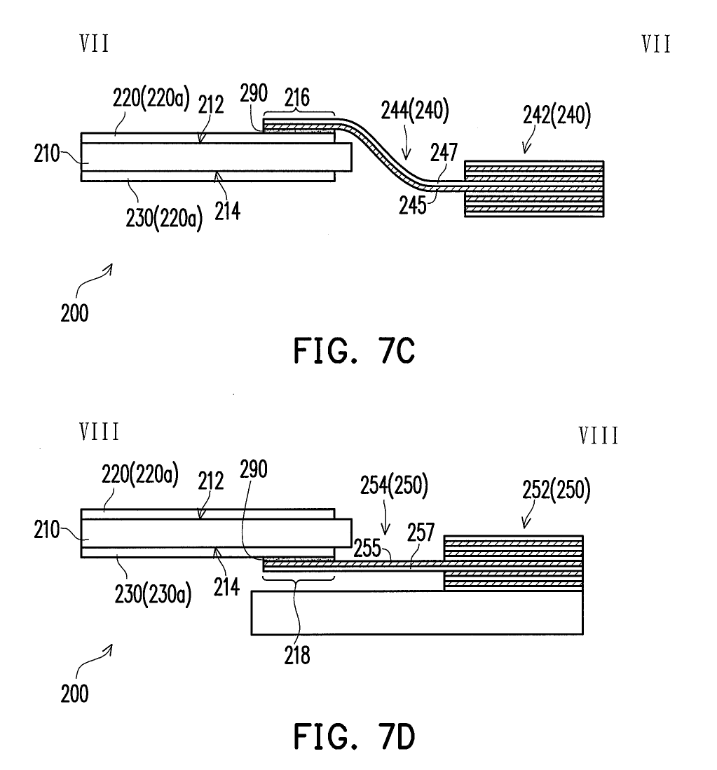

FIG. 7A is a top view of a touch panel according to still another embodiment of the invention. FIG. 7B is a bottom view of the touch panel of FIG. 7A. Referring to FIG. 7A and FIG. 7B, in the present embodiment, the touch panel 200 includes a substrate 210, a first patterned conductive layer 220, a second patterned conductive layer 230, a first circuit board 240, a second circuit board 250 and a connection circuit 260.

In detail, the substrate 210 has a first surface 212, a second surface 214, a first bonding area 216 located at an edge of the first surface 212 and a second bonding area 218 located at an edge of the second surface 214. The first patterned conductive layer 220 is disposed on the first surface 212 and includes a plurality of first sensing series 220a electrically insulated from each other, wherein an end of each first sensing series 220a extends to the first bonding area 216. The second patterned conductive layer 230 is disposed on the second surface 214 and includes a plurality of second sensing series 230a electrically insulated from each other, wherein an end of each second sensing series 230a extends to the second bonding area 218.

In the present embodiment, the substrate 210 is, for example, a transparent substrate, an opaque substrate, or a translucent substrate, wherein a material of the substrate 210 is preferably glass, polycarbonate (PC), polymethyl methacrylate (PMMA) or polyethylene terephthalate (PET), and a thickness of the substrate 210 is preferably between about 0.1 mm and about 2 mm. Moreover, the first patterned conductive layer 220 and the second patterned conductive layer 230 are, for example, respectively a transparent patterned conductive layer, an opaque patterned conductive layer or a translucent patterned conductive layer, wherein a material of the first patterned conductive layer 220 and the second patterned conductive layer 230 is preferably indium tin oxide, transparent conducting oxide (TCO) or a transparent conductive material containing nano-materials. If the first patterned conductive layer 220 and the second patterned conductive layer 230 are all fabricated by the transparent conductive material, the touch panel 200 of the present embodiment may provide a good light penetrability.

FIG. 7C is a cross-sectional view of the touch panel of FIG. 7A along a VII-VII line. FIG. 7D is a cross-sectional view of the touch panel of FIG. 7A along a VIII-VIII line. Referring to FIG. 7A, FIG. 7B, FIG. 7C and FIG. 7D, particularly, the first circuit board 240 of the touch panel 200 includes a first rigid portion 242 and a first flexible bonding portion 244 electrically connected to the first rigid portion 242. The first flexible bonding portion 244 is electrically connected to the first sensing series 220a in the first bonding area 216. The second circuit board 250 includes a second rigid portion 252 and a second flexible bonding portion 254 electrically connected to the second rigid portion 252. The second flexible bonding portion 254 is electrically connected to the second sensing series 230a in the second bonding area 218. The connection circuit 260 is electrically connected to the first rigid portion 242 and the second rigid portion 252. In the present embodiment, the connection circuit 260 is, for example, a flexible printed circuit (FPC), which is used for connecting the first circuit board 240 and the second circuit board 250.

Referring to FIG. 7C and FIG. 7D, it should be noticed that in the present embodiment, the first rigid portion 242 of the first circuit board 240 includes a plurality of conductive layers 245 and dielectric layers 247 stacked alternately, wherein a part of the conductive layers 245 and the dielectric layers 247 in the first rigid portion 242 extends outward to form the first flexible bonding portion 244. The second rigid portion 252 of the second circuit board 250 includes a plurality of conductive layers 255 and dielectric layers 257 stacked alternately, wherein a part of the conductive layers 255 and the dielectric layers 257 in the second rigid portion 252 extends outward to form the second flexible bonding portion 254. Namely, the structures of the first circuit board 240 and the second circuit board 250 can be regarded as flexible-hard board structures. In the present embodiment, shapes of the first rigid portion 242 of the first circuit board 240 and the second rigid portion 252 of the second circuit board 250 are, for example, strip shapes.

Moreover, referring to FIG. 7A, FIG. 7B, FIG. 7C and FIG. 7D, the touch panel 200 of the present embodiment further includes two anisotropic conductive films 290, wherein the anisotropic conductive films 290 are respectively disposed between the end of the first sensing series 220a and the first flexible bonding portion 244 of the first circuit board 240, and between the end of the second sensing series 230a and the second flexible bonding portion 254 of the second circuit board 250. Namely, the anisotropic conductive films 290 directly contact to the first patterned conductive layer 220 and the second patterned conductive layer 230. Since the anisotropic conductive films 290 directly contact to the first patterned conductive layer 220 and the second patterned conductive layer 230, adhesions respectively between the first flexible bonding portion 244 and the substrate 210, and the second flexible bonding portion 254 and the substrate 210 are increased, and generation of contact impedance is reduced.

Moreover, the touch panel 200 of the present embodiment includes at least a chip 270 and a control circuit 280, wherein the chip 270 is disposed on the connection circuit 260, and is electrically connected to the connection circuit 260. The first patterned conductive layer 220 and the second patterned conductive layer 230 may transmit signals to the chip 270 through the connection circuit 260, so as to calculate coordinates of a touch point (not shown). The control circuit 280 is electrically connected to the connection circuit 260, and the first patterned conductive layer 220 and the second patterned conductive layer 230 are electrically connected to the control circuit 280 through the first circuit board 240, the second circuit board 250 and the connection circuit 260. It should be noticed that since the chip 270 is disposed on the connection circuit 260, such configuration can be regarded as chip-on-film (COF).

It should be noticed that in other embodiments that are not illustrated, elements such as the aforementioned support board 180, the protection films 190 etc. can also be used, and those skilled in the art can determine the used elements according to an actual requirement, so as to achieve a required technical effect.

Since the first patterned conductive layer 220 and the second patterned conductive layer 230 of the present embodiment are respectively disposed on the first surface 212 and the second surface 214 of the substrate 210, the touch panel 200 of the present embodiment can be regarded as a double-sided touch panel. Moreover, since the first patterned conductive layer 220 and the second patterned conductive layer 230 of the present embodiment all apply the design of unilateral output, when the first circuit board 240 and the second circuit board 250 are respectively assembled to the substrate 210 for electrically connecting the first sensing series 220a and the second sensing series 230a, an assembling rate and an yield rate thereof are increased.

Moreover, since the first circuit board 240 simultaneously has the first rigid portion 242 and the first flexible bonding portion 244, the second circuit board 250 simultaneously has the second rigid portion 252 and the second flexible bonding portion 254, and since the first flexible bonding portion 244 and the second flexible bonding portion 254 are respectively formed by extending out a part of the conductive layers 245 and 255 and the dielectric layers 247 and 257 in the first rigid portion 242 and the second rigid portion 252, the first patterned conductive layer 220 and the second patterned conductive layer 230 on the substrate 210 can be directed connected to the first flexible bonding portion 244 and the second flexible bonding portion 254, and the first circuit board 240 and the second circuit board 250 can be electrically connected to an external circuit (for example, the control circuit 280) through the connection circuit 260. In this way, a production cost of the touch panel 200 of the present embodiment can be effectively reduced, and assembling steps thereof can be simplified, so as to increase a throughput and operation convenience thereof, and the touch panel 200 is easy to rework.

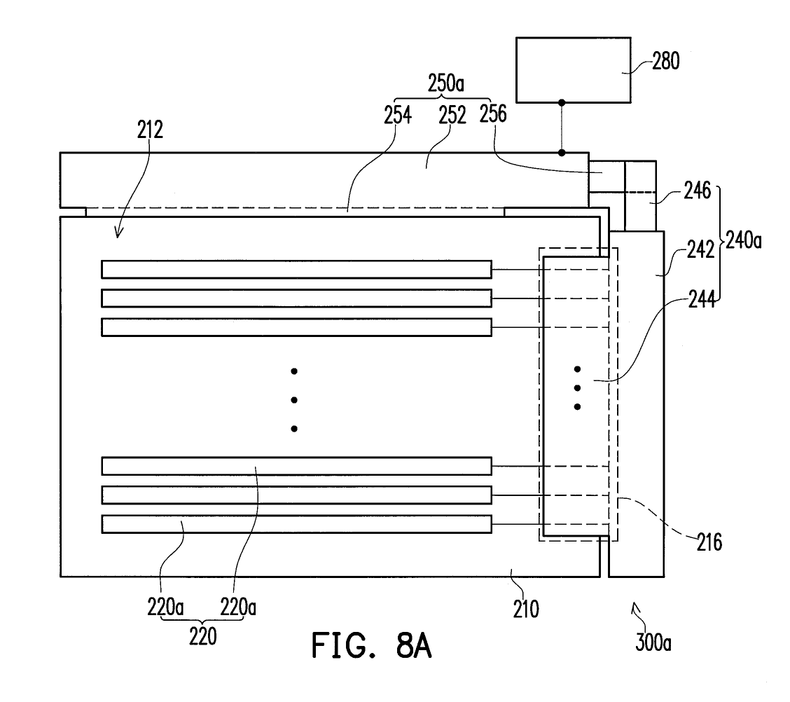

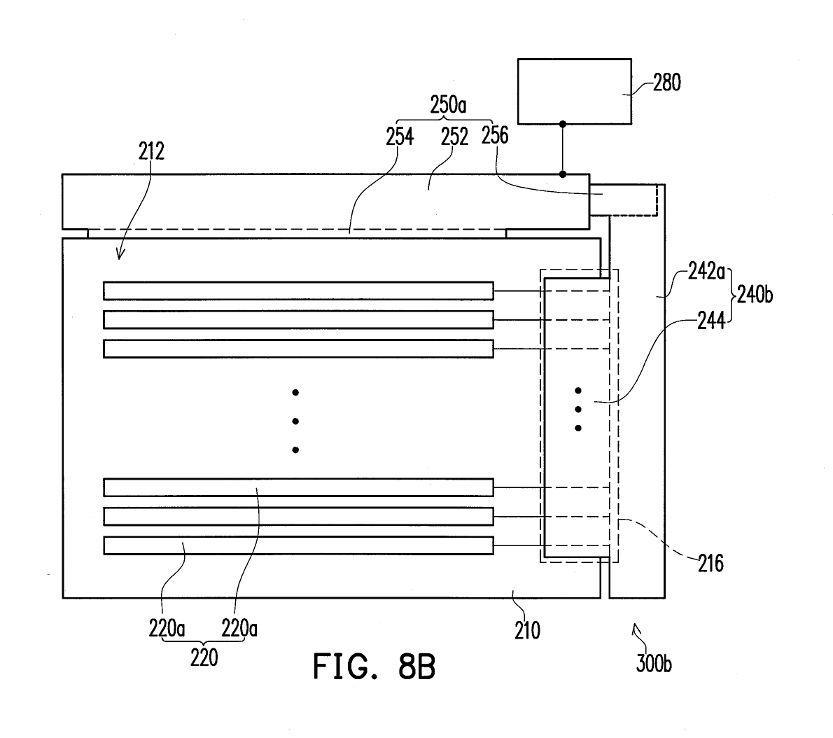

FIG. 8A is a top view of a touch panel according to still another embodiment of the invention. Referring to FIG. 8A and FIG. 7A, in the present embodiment, the touch panel 300a of FIG. 8A is similar to the touch panel 200 of FIG. 7A, and differences there between are that the touch panel 300a of FIG. 8 does not have the chip, and the first circuit board 240a of the touch panel 300a further includes a third flexible bonding portion 246, and the second circuit board 250a further includes a fourth flexible bonding portion 256, wherein the first circuit board 240a and the second circuit board 250a are electrically connected by connecting the third flexible bonding portion 246 and the fourth flexible bonding portion 256. Certainly, in another embodiment, referring to FIG. 8B, the first circuit board 240b of the touch panel 300b does not have the third flexible bonding portion, and the fourth flexible bonding portion 256 of the second circuit board 250a is connected to the first rigid portion 242a of the first circuit board 240b. Since the touch panels 300a and 300b of the present embodiment does not have the chip, a risk of damage thereof can be reduced.

In summary, since the touch panel of the invention applies the circuit board having both of the rigid portion and the flexible bonding portions, the first patterned conductive layer and the second patterned conductive layer on the substrate can be directly connected to the flexible bonding portions, and the chip or the control circuit can be directly connected to the circuit board. In this way, a production cost of the touch panel is reduced, and throughput and yield rate thereof are increased.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A touch panel, comprising:
a substrate having a first surface, a second surface, a first bonding area located at an edge of the first surface and a second bonding area located at an edge of the second surface;
a first patterned conductive layer disposed on the first surface and comprising a plurality of first sensing series electrically insulated from each other, wherein an end of each first sensing series extends to the first bonding area;
a second patterned conductive layer disposed on the second surface and comprising a plurality of second sensing series electrically insulated from each other, wherein an end of each second sensing series extends to the second bonding area; and
a circuit board comprising a rigid portion, a first flexible bonding portion and a second flexible bonding portion, wherein the first flexible bonding portion and the second flexible bonding portion are electrically connected to the rigid portion, the first flexible bonding portion is electrically connected to the first sensing series in the first bonding area, and the second flexible bonding portion is electrically connected to the second sensing series in the second bonding area.

2. The touch panel as claimed in claim 1, wherein a material of the substrate comprises glass, polycarbonate (PC), polymethyl methacrylate (PMMA) or polyethylene terephthalate (PET).

3. The touch panel as claimed in claim 1, wherein the substrate is a transparent substrate, an opaque substrate or a translucent substrate.

4. The touch panel as claimed in claim 1, wherein a thickness of the substrate is between about 0.1 mm and about 2 mm.

5. The touch panel as claimed in claim 1, wherein each of the first sensing series comprises:
a plurality of first sensing pads; and
a plurality of first bridge portions, wherein each of the first bridge portions is electrically connected between two neighboring first sensing pads.

6. The touch panel as claimed in claim 1, wherein each of the second sensing series comprises:
a plurality of second sensing pads; and
a plurality of second bridge portions, wherein each of the second bridge portions is electrically connected between two neighboring second sensing pads.

7. The touch panel as claimed in claim 1, wherein a material of the first patterned conductive layer and the second patterned conductive layer comprises indium tin oxide (ITO), transparent conducting oxide (TCO) or a transparent conductive material containing nano-materials.

8. The touch panel as claimed in claim 1, wherein the first patterned conductive layer is a transparent patterned conductive layer, an opaque patterned conductive layer or a translucent patterned conductive layer.

9. The touch panel as claimed in claim 1, wherein the second patterned conductive layer is a transparent patterned conductive layer, an opaque patterned conductive layer or a translucent patterned conductive layer.

10. The touch panel as claimed in claim 1, wherein the rigid portion of the circuit board comprises a plurality of conductive layers and dielectric layers stacked alternately, and a part of the conductive layers and the dielectric layers in the rigid portion extends outward to form the first flexible bonding portion and the second flexible bonding portion.

11. The touch panel as claimed in claim 1, wherein a shape of the rigid portion of the circuit board comprises an L-shape.

12. The touch panel as claimed in claim 1, further comprising at least a chip disposed on the rigid portion of the circuit board, wherein the chip is electrically connected to the circuit board.

13. The touch panel as claimed in claim 1, further comprising a control circuit electrically connected to the circuit board, wherein the first patterned conductive layer and the second patterned conductive layer are electrically connected to the control circuit through the circuit board.

14. The touch panel as claimed in claim 13, further comprising at least a chip disposed on the control circuit, wherein the chip is electrically connected to the control circuit.

15. The touch panel as claimed in claim 1, further comprising two anisotropic conductive films respectively disposed between the end of the first sensing series and the first flexible bonding portion of the circuit board, and between the end of the second sensing series and the second flexible bonding portion of the circuit board.

16. The touch panel as claimed in claim 1, further comprising a support board, wherein the circuit board is disposed on the support board, and the support board surrounds the substrate.

17. The touch panel as claimed in claim 16, wherein a shape of the support board comprises an L-shape, a [symbol] -shape or a □-shape.

18. The touch panel as claimed in claim 1, further comprising at least a protection film disposed on the substrate, wherein the protection film covers the first patterned conductive layer or the second patterned conductive layer.

19. The touch panel as claimed in claim 18, wherein the protection film comprises an anti-reflection film, an anti-glare film, an anti-grease film or a circuit visibility reduction film.

20. A touch panel, comprising:
a substrate having a first surface, a second surface, a first bonding area located at an edge of the first surface and a second bonding area located at an edge of the second surface;
a first patterned conductive layer disposed on the first surface and comprising a plurality of first sensing series electrically insulated from each other, wherein an end of each first sensing series extends to the first bonding area;
a second patterned conductive layer disposed on the second surface and comprising a plurality of second sensing series electrically insulated from each other, wherein an end of each second sensing series extends to the second bonding area;
a first circuit board comprising a first rigid portion and a first flexible bonding portion electrically connected to the first rigid portion, wherein the first flexible bonding portion is electrically connected to the first sensing series in the first bonding area;
a second circuit board comprising a second rigid portion and a second flexible bonding portion electrically connected to the second rigid portion, wherein the second flexible bonding portion is electrically connected to the second sensing series in the second bonding area; and
a connection circuit electrically connected to the first rigid portion and the second rigid portion.

21. The touch panel as claimed in claim 20, wherein a material of the substrate comprises glass, polycarbonate (PC), polymethyl methacrylate (PMMA) or polyethylene terephthalate (PET).

22. The touch panel as claimed in claim 20, wherein the substrate is a transparent substrate, an opaque substrate or a translucent substrate.

23. The touch panel as claimed in claim 20, wherein a thickness of the substrate is between about 0.1 mm and about 2 mm.

24. The touch panel as claimed in claim 20, wherein each of the first sensing series comprises:
a plurality of first sensing pads; and
a plurality of first bridge portions, wherein each of the first bridge portions is electrically connected between two neighboring first sensing pads.

25. The touch panel as claimed in claim 20, wherein each of the second sensing series comprises:
a plurality of second sensing pads; and
a plurality of second bridge portions, wherein each of the second bridge portions is electrically connected between two neighboring second sensing pads.

26. The touch panel as claimed in claim 20, wherein a material of the first patterned conductive layer and the second patterned conductive layer comprises indium tin oxide (ITO), transparent conducting oxide (TCO) or a transparent conductive material containing nano-materials.

27. The touch panel as claimed in claim 20, wherein the first patterned conductive layer is a transparent patterned conductive layer, an opaque patterned conductive layer or a translucent patterned conductive layer.

28. The touch panel as claimed in claim 20, wherein the second patterned conductive layer is a transparent patterned conductive layer, an opaque patterned conductive layer or a translucent patterned conductive layer.

29. The touch panel as claimed in claim 20, wherein the first rigid portion of the first circuit board and the second rigid portion of the second circuit board respectively comprise a plurality of conductive layers and dielectric layers stacked alternately, and a part of the conductive layers and the dielectric layers in the first rigid portion and the second rigid portion extend outward to form the first flexible bonding portion and the second flexible bonding portion.

30. The touch panel as claimed in claim 20, wherein shapes of the first rigid portion of the first circuit board and the second rigid portion of the second circuit board comprise strip shapes.

31. The touch panel as claimed in claim 20, further comprising at least a chip disposed on the connection circuit, wherein the chip is electrically connected to the connection circuit.

32. The touch panel as claimed in claim 20, further comprising a control circuit electrically connected to the connection circuit, wherein the first patterned conductive layer and the second patterned conductive layer are electrically connected to the control circuit through the first circuit board, the second circuit board and the connection circuit.

33. The touch panel as claimed in claim 20, wherein the connection circuit comprises a flexible printed circuit.

34. The touch panel as claimed in claim 20, further comprising two anisotropic conductive films respectively disposed between the end of the first sensing series and the first flexible bonding portion of the first circuit board, and between the end of the second sensing series and the second flexible bonding portion of the second circuit board.

35. The touch panel as claimed in claim 20, further comprising a support board, wherein at least the first circuit board and the second circuit board are disposed on the support board, and the support board surrounds the substrate.

36. The touch panel as claimed in claim 35, wherein a shape of the support board comprises an L-shape, a [symbol] -shape or a □-shape.

37. The touch panel as claimed in claim 20, further comprising at least a protection film disposed on the substrate, wherein the protection film covers the first patterned conductive layer or the second patterned conductive layer.

38. The touch panel as claimed in claim 37, wherein the protection film comprises an anti-reflection film, an anti-glare film, an anti-grease film or a circuit visibility reduction film.

39. The touch panel as claimed in claim 20, wherein the first circuit board further comprises a third flexible bonding portion, the second circuit board further comprises a fourth flexible bonding portion, and the first circuit board and the second circuit board are electrically connected by connecting the third flexible bonding portion and the fourth flexible bonding portion.

40. The touch panel as claimed in claim 20, wherein the second circuit board further comprises a fourth flexible bonding portion, and the fourth flexible bonding portion is connected to the first rigid portion of the first circuit board.
